(19) United States
(12) Patent Application Publication
(10) Pub. No.: US 2005/0089770 A1
(43) Pub. Date: Apr. 28, 2005

(54) Printing irregularly-spaced contact holes using phase shift masks

(76) Inventor: Yong Liu, Fremont, CA (US)

Correspondence Address: Law Office of Roxana H. Yang, P.O. Box 400, Los Altos, CA, 94023, US

(21) Appl. No.: 10/973,001

(22) Filed: Oct. 25, 2004

Related U.S. Application Data
(60) Provisional application No. 60/514,227, filed on Oct. 24, 2003.
(60) Provisional application No. 60/517,741, filed on Nov. 5, 2003.

(51) Int. Cl. G03F 9/00; G06F 17/50

(52) U.S. Cl. 430/5; 430/322; 716/19

(57) ABSTRACT

An exemplary method for printing irregularly-spaced contact holes of a semiconductor device comprises printing a semiconductor wafer using at least one multi-phase phase shift mask. The mask has a plurality of polygons on a substrate, where at least one of the polygons is irregularly-spaced with respect to another polygon, and one or more of polygons provide sufficient phase shift relative to an exterior region of the polygons to effect destructive light interference for printing irregularly-spaced contact holes on one or more phase shift edges.

### REFERENCE TO RELATED APPLICATIONS

This application claims priority to provisional patent applications filed on Oct. 24, 2003, bearing application Ser. No. 60/514,227 and Nov. 5, 2003, bearing application Ser. No. 60/517,741.

### BACKGROUND

Photolithography is a basic technique for forming patterns in semiconductor manufacturing processes. Photolithography generally involves: (1) coating a wafer with a photoresist material; (2) placing a mask having desired patterns above the wafer; and (3) exposing the mask and wafer to light. Light exposure causes a chemical reaction in the photoresist which enables the transfer (or printing) of the mask patterns. The wafer is then generally subject to a development process to remove portions of the photoresist (either the exposed portions or the unexposed portions, depending on the type of photoresist used) while retaining the desired printed patterns. There are generally two types of photoresists: positive photoresist and negative photoresist. When a positive photoresist is used, the exposed portions are removed during development. When a negative photoresist is used, the unexposed portions are removed during development. For ease of explanation only, throughout this application, various exemplary implementations are described as using the negative photoresist. One skilled in the art will readily recognize that the positive photoresist may be used instead in accordance with design requirements or preferences.

In semiconductor manufacturing, device miniaturization has always been one of the most important research and development goals. One way to achieve this goal is to print (and develop) smaller contact holes in the semiconductor devices, for example, by using masks having smaller contact hole dimensions.

However, resolution of the printed patterns worsens as contact hole dimensions become smaller. This is the result of optical diffraction. As pattern dimensions shrink, exposure light passing through the openings on the mask will also expose unintended areas around the openings. The exposure of unintended areas will cause a reduction in light contrast, resulting in degraded pattern resolution.

One technique to improve pattern resolution is to use the so-called phase shift masks. Conventional masks used in photolithography are generally referred to as binary masks. Binary masks are typically made by forming patterned opaque materials (such as chromium) on a transparent substrate (such as glass). In a phase shift mask, however, one or more phase shifting materials (e.g., phase shifters) are formed on a transparent substrate (with or without the opaque materials) to change the phase of light passing through such phase shifters by a predetermined amount (e.g., 90°, 180°, 270°, etc.). It is generally understood that the tranmission coefficients of light through both the transparent substrate and phase shifters of different phases are substantially the same. A phase shift mask typically has multiple regions having different (e.g., alternating) phase shifters.

For example, a phase shift mask may have a first region having 0° phase and a second region having 180° phase. In this example, when the phase shift mask (placed above a wafer coated with photoresist) is exposed to light, light passing through the first region having 0° phase and the second region having 180° phase will cancel each other in any overlapping areas, thereby printing a thin, well defined line(s) at the edge(s) separating the two regions. Due to optical interference, light intensity is reduced at the overlapping regions and greater difference in light intensity between the two exposed regions on the wafer can be achieved. As a result, better defined patterns can be formed.

FIGS. 1A and 1B illustrate exemplary phase shift masks known in the art that can be used to form regularly-space (or grid) contact holes. In FIG. 1A, rectangular phase shifters (indicated by filled rectangles) are oriented vertically at regular intervals on a glass substrate. These rectangular phase shifters shift any light passing through them by 180° phase relative to the glass substrate. FIG. 1B has similar features except its rectangular phase shifters are oriented horizontally. The phase shift masks in FIGS. 1A and 1B can be used to pattern a wafer coated with a photoresist by successively exposing the wafer to light passing through these masks. During the first exposure (with the mask of FIG. 1A), light in the 0° region and 180° region destructively interferes with each other at the edges of the vertical rectangular phase shifters, thereby printing the resist image of thin dark lines forming vertically-oriented rectangles (indicating unexposed areas). During the second exposure (with the mask of FIG. 1B), light in the 0° region and 180° region destructively interfere with each other at the edges of the horizontal rectangular phase shifters, thereby printing the resist image of an array of dark dots (indicating unexposed areas) at the intersections of the vertically-oriented and horizontally-oriented rectangles. The horizontally-oriented rectangles are not printed on the wafer because the portions of the wafer covered by these rectangles were previously exposed during the first exposure. FIG. 2 illustrates an exemplary array of the unexposed dots. Most regions unexposed by the first exposure are exposed by light in the second exposure. Due to optical interference, the intersections between the previously printed dark lines and the edges of the horizontal rectangular phase shifters remain unexposed. The unexposed dots may later be developed into contact holes.

One technique to control the size of these regularly-spaced contact holes is to form an opaque material (e.g., a thin layer of chromium) or the so-called regulators along the edges of the vertical and horizontal rectangular phase shifters described in the example above. Exemplary phase shift masks implementing chromium regulators are illustrated in FIGS. 3A and 3B. The regulators provide more control over the size (and may also improve the resolution) of the resulting printed patterns by preventing light transmission in the opaque areas.

Existing techniques implementing phase shift masks to print contact holes generally result in regularly-spaced contact holes. In practice, however, most semiconductor devices require irregularly-spaced contact holes.

Three-phase phase shift masks may be implemented to print single contact holes at desired locations of a semiconductor device. FIGS. 4A-4B illustrate exemplary three-phase phase shift masks that may be used in successive exposures (as described above) to print a contact hole as illustrated in FIG. 4C. In FIGS. 4A-4B, two phase shifters having opposite phases (i.e., 90° & −90°) are formed on a glass substrate having 0° phase. In FIG. 4A, the two shifters are oriented vertically. In FIG. 4B, the two shifters are oriented horizontally. If a wafer coated with a photoresist is successively exposed by light passing through these masks aligned orthogonally relative to each other, a small unexposed dot will print at the intersection of the centers of the two shifters of the masks where the phase difference is 180°. The unexposed dot can be developed into a single contact hole. The small light intensity drop resulting from the 90° phase transition between phase shifters (other than at the intersection(s) of the centers) will not print in the photoresist.

Although the three-phase phase shift masks may be used to print single contact holes which may be irregularly spaced, this technique typically requires multiple layers of phase-shifters; thus, it's too costly to be widely implemented in practice.

Thus, a market exists for techniques to use phase shift masks to print irregularly-spaced contact holes.

### SUMMARY

An exemplary method for printing irregularly-spaced contact holes of a semiconductor device comprises printing a semiconductor wafer using at least one multi-phase phase shift mask. The mask has a plurality of polygons on a substrate, where at least one of the polygons is irregularly-spaced with respect to another polygon, and one or more of polygons provide sufficient phase shift relative to an exterior region of the polygons to effect destructive light interference for printing irregularly-spaced contact holes along one or more phase shift edges.

An exemplary method for forming phase shift masks for printing irregularly-spaced contact holes on a semiconductor wafer comprises classifying contact holes into groups, each group comprising at least two contact holes, designing a first set of polygons, each of the first set of polygons intersecting all contact holes of one group, and at least one polygon of the first set being irregularly-spaced with respect to one or more other polygons of the first set, designing a second set of polygons, each of the second set of polygons intersecting at least one polygon of the first set at the locations of the contact holes being intersected by the at least one polygon of the first set, forming a phase shifter in an interior region of each polygon such that the interior region provides sufficient phase shift relative to an exterior region of the polygon to effect destructive light interference during a light exposure for printing irregularly-spaced contact holes along one or more phase shift edges, and forming one or more phase shift masks based on the first and second sets of polygons.

These and other exemplary embodiments and implementations are disclosed herein.

### BRIEF DESCRIPTION OF THE FIGURES

FIGS. 1A and 1B illustrate an exemplary set of two phase shift masks to be used to print an array of regularly-spaced contact holes.

FIG. 2 illustrates an array of regularly-spaced unexposed dots printed on a wafer using the phase shift masks of FIGS. 1A and 1B.

FIGS. 3A and 3B illustrate exemplary phase shift masks having regulators.

FIGS. 4A and 4B illustrate exemplary three-phase phase shift masks.

FIG. 4C illustrates an exemplary contact hole printed by using the phase shift masks of FIGS. 4A and 4B.

FIG. 5A-5B illustrate exemplary phase shift masks for printing a pair of irregularly-spaced contact holes.

FIG. 5C illustrate exemplary contact holes printed by using the phase shift masks of FIGS. 5A and 5B.

FIGS. 6A-6F illustrate exemplary alignments of polygons for printing irregularly-spaced contact holes.

FIGS. 6G-6J illustrate other exemplary alignments and shapes of polygons for printing irregularly-spaced contact holes.

FIG. 7 illustrates an exemplary alignment of two sets of polygons for printing irregularly-spaced contact holes of a RAM device.

FIG. 8 illustrates another exemplary alignment of two sets of polygons for printing irregularly-spaced contact holes of another SRAM device.

FIG. 9 illustrates another exemplary alignment of two sets of polygons for printing irregularly-spaced contact holes of an ALU device.

FIG. 10A illustrates an exemplary location for placing a redundant hole.

FIG. 10B illustrates an exemplary implementation for designing and aligning polygons for printing irregularly-spaced contact holes as illustrated in FIG. 10A.

FIG. 11A illustrates an exemplary polygon that can be used to print a bar-shaped resist image.

FIG. 11B illustrates exemplary polygons of two phase shift masks that can be used to print a single contact hole.

FIGS. 12A and 12B illustrate exemplary contact hole sizes and shapes and exemplary resist images thereof.

FIGS. 13A-13D illustrates an exemplary technique for controlling the size (and/or shape) of contact holes.

FIG. 14A illustrates light intensity at different planes when applying the technique of FIG. 13.

FIG. 14B illustrates light intensity at different planes when not applying the technique of FIG. 13.

FIGS. 15A and 15B illustrates another exemplary technique for controlling the size (and/or shape) of contact holes.

FIGS. 16A and 16B illustrate exemplary placements of contact holes on metal lines.

FIG. 17 illustrates potential misalignment errors.

FIGS. 18A and 18B illustrate an exemplary printing error and error correction.

FIGS. 19A-19J illustrate exemplary alignments of polygons of three-phase phase shift masks to print irregularly-spaced contact holes.

FIG. 20 illustrates exemplary polygons of a four-phase phase shift mask.

FIG. 21 illustrates exemplary polygons of a four-phase phase shift mask adapted from two polygons of two-phase phase shift masks.

FIGS. 22A-22J illustrate exemplary alignments of polygons of a four-phase phase shift mask (vortex mask) to print irregularly-spaced contact holes

FIG. 23 illustrates an exemplary alignment of polygons of a four-phase phase shift mask (vortex mask) for printing irregularly-spaced contact holes of a SRAM device.

FIG. 24 illustrates an exemplary process for designing polygons of phase-shift mask(s) for printing irregularly-spaced contact holes.

FIG. 25 illustrates an exemplary technique for resolving a phase conflict.

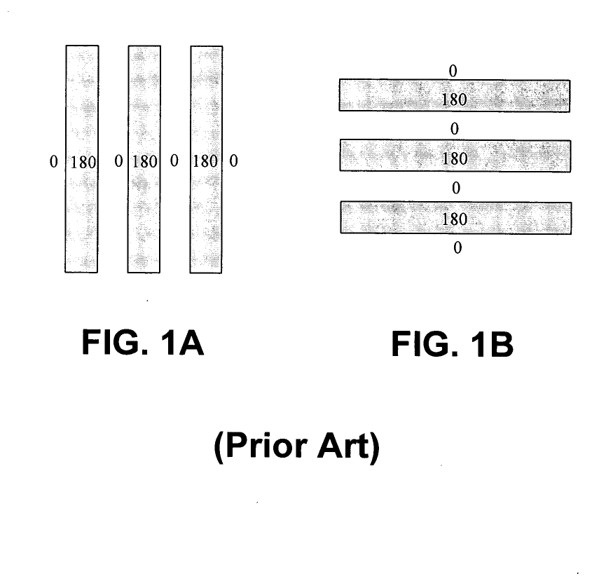

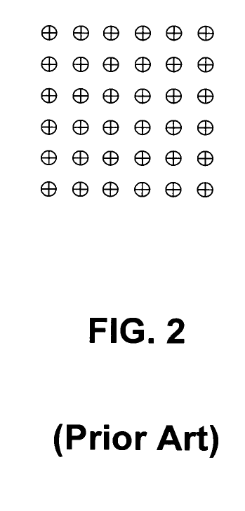

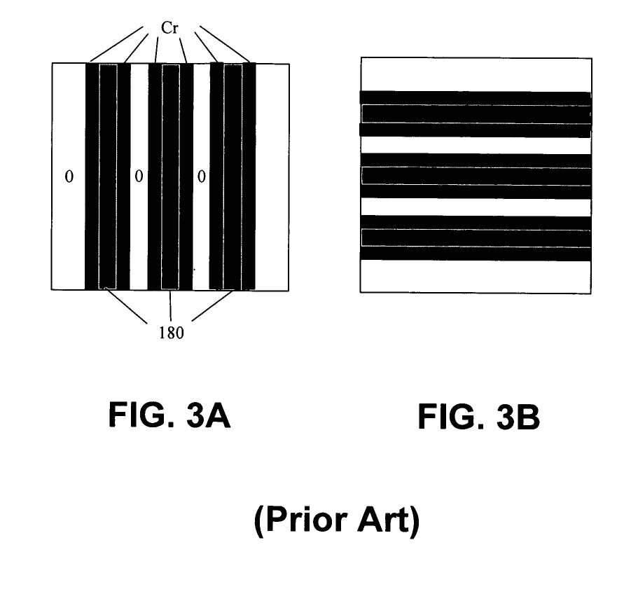

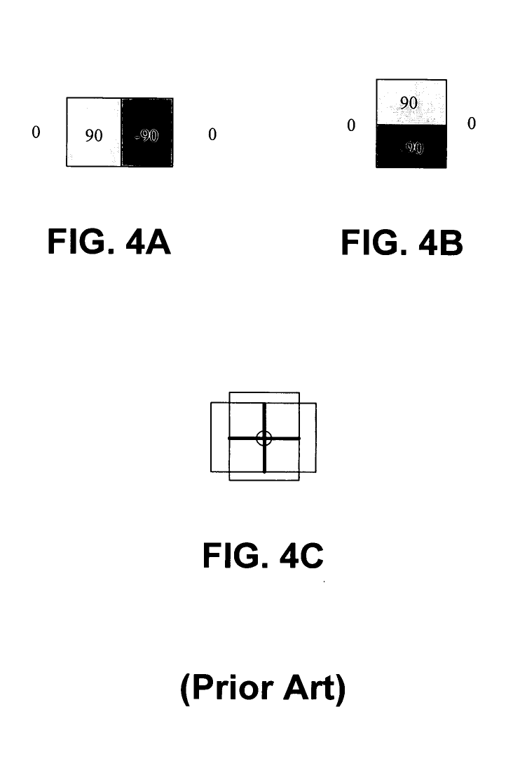

### DETAILED DESCRIPTION

I. Overview

Techniques for using phase shift masks to print irregularly-spaced contact holes on a wafer are disclosed herein. For ease of explanation, throughout this application, the term contact holes will be used. However, this term shall include, without limitation, vias, posts (e.g., if positive photoresist is used), and/or other similar features on a device.

Section II describes exemplary implementations for aligning two sets of polygons (e.g., of two phase shift masks) for printing irregularly-spaced contact holes.

Section III describes exemplary implementations for printing redundant and/or single contact holes to complement the implementations described in Section II.

Section IV describes exemplary implementations for enabling printing of contacts holes of different sizes and shapes.

Section V describes potential errors and exemplary error correction techniques.

Section VI describes exemplary embodiments for implementing other phase shift masks (e.g., three-phase or four-phase masks) to print irregularly-spaced contact holes.

Section VII describes an exemplary process for designing polygons of phase shift mask(s) in accordance with the exemplary implementations described herein.

Section VIII describes exemplary techniques for resolving a phase conflict.

Section IX describes an exemplary operating environment.

II. Exemplary Polygons of Phase Shift Masks for Printing Irregularly-Spaced Contact Holes

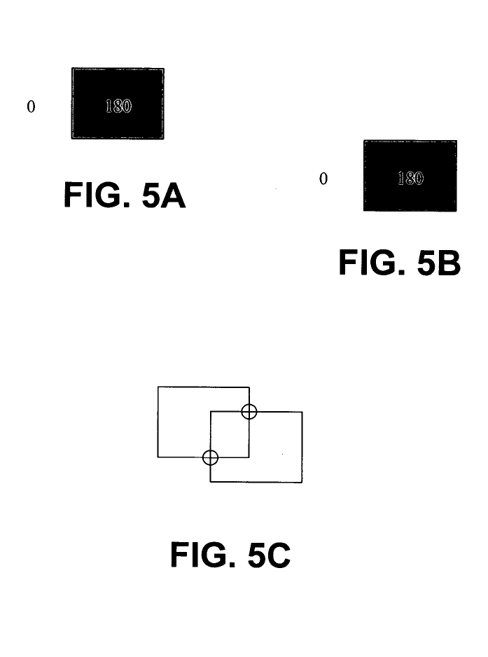

FIG. 5A illustrates an exemplary phase shift mask including a phase shifter polygon formed on a glass substrate. The interior region of the polygon shifts the phase of light passing through it by 180°. In various exemplary implementations described herein, a phase shift mask generally includes at least two phase regions. The first region and the second region generally have a relative phase shift difference of 180°. For example, all interior areas of polygons on a mask can be considered the first region and all areas outside the polygons can be considered the second region. The absolute phase shift value of each region is not material, as long as the relative phase shift difference is large enough (e.g., 180°) to print contact holes in accordance with exemplary implementations described herein. For example, one region may have a phase shift of 90° while another region has a phase shift of 270° (or −90°), and so forth. For ease of explanation, most of the exemplary implementations described herein (except in Section VI) will refer to the interior areas of polygons on a phase shift mask as having a 180° phase shift and the areas outside the polygons as having a phase shift of 0°. Further, the term “polygon” as used herein shall not be limited to shapes having more than one side. For example, a “polygon” may also include, without limitation, circles, ellipses, ovals, or any other shapes having smooth curves.

FIG. 5B illustrates another exemplary phase shift mask including a polygon formed on a glass substrate. The polygon shifts the phase of light passing through it by 180° relative to the glass substrate. FIG. 5C illustrates an exemplary alignment of the two polygons of the two phase shift masks illustrated in 5A and 5B. At the two locations where the polygons intersect each other, two irregularly-spaced contact holes can be printed on a wafer (e.g., by exposing the wafer successively with the phase shift masks of FIGS. 5A and 5B).

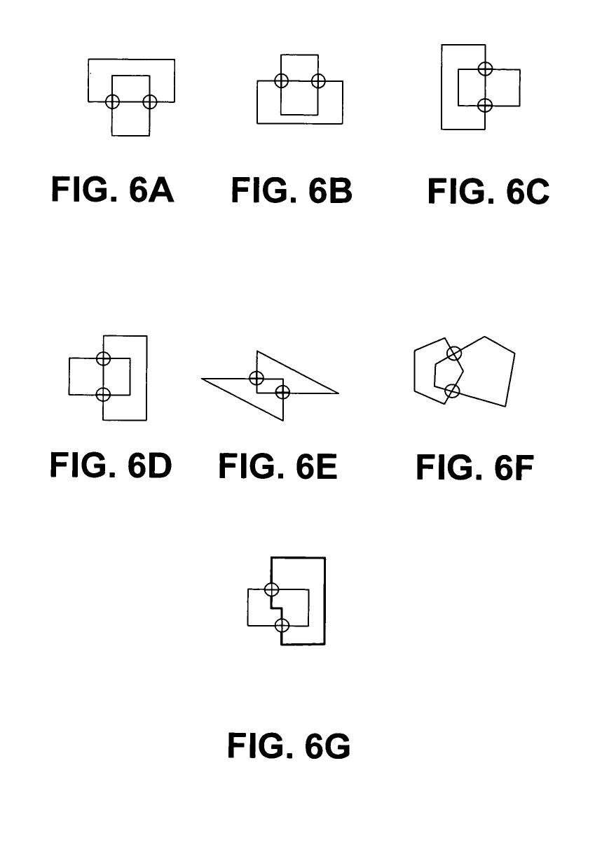

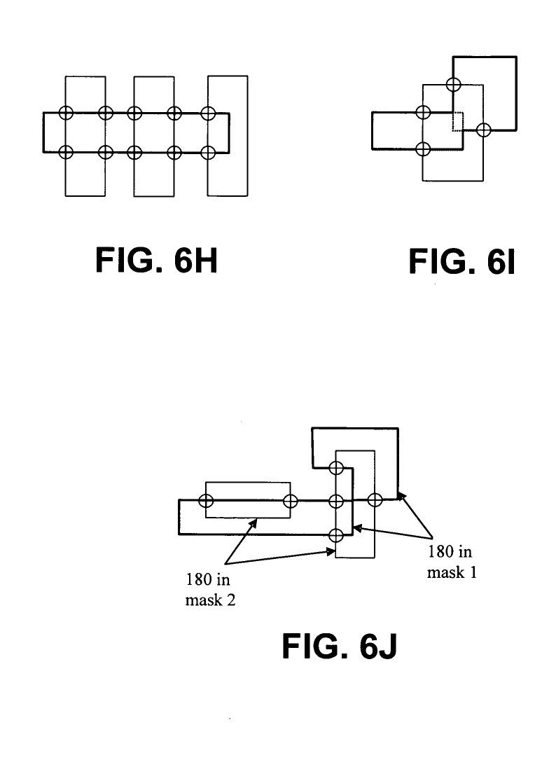

FIGS. 6A-6G illustrate other exemplary pairs of polygons (e.g., of different phase shift masks) intersecting each other to enable printing of two irregularly-spaced contact holes at their intersections. In an exemplary implementation, in each figure, each of the two polygons belongs to a different phase shift mask. One skill in the art will recognize that polygons may be designed to have any shape and size depending on design choice.

In general, when two phase shift masks are used to print irregularly-spaced contact holes, polygons of the first phase shift mask should intersect with polygons of the second phase shift mask only at the locations of the desired contact holes (including intentionally inserted redundant holes). These intersecting polygon pairs can be called companion polygons. However, polygons of the same phase shift mask may intersect other polygons of the same mask at any location.

FIGS. 6H-6J illustrate exemplary sets of polygons (e.g., of two phase shift masks). In each figure, one or more polygons of a first set intersects one or more polygons of a second set to enable printing of more than two irregularly-spaced contact holes at their intersections. For example, in FIG. 6H, three polygons of a first set (thin line) and one polygon of a second set (thick line) intersect each other at ten places to enable printing of ten contact holes. In FIG. 6I, one polygon of a first set (thin line) and two polygons of a second set (thick line) intersect each other at four places to enable printing of four contact holes. In FIG. 61, two polygons of the second set also intersect each other. No contact holes are printed when polygons of the same set intersect each other because all interior areas of polygons of the same set have the same phase shift and are exposed at the same time. In FIG. 6J, two polygons from a first set (thin line) and two polygons from a second set (thick line) intersect each other at six places to enable printing of six contact holes.

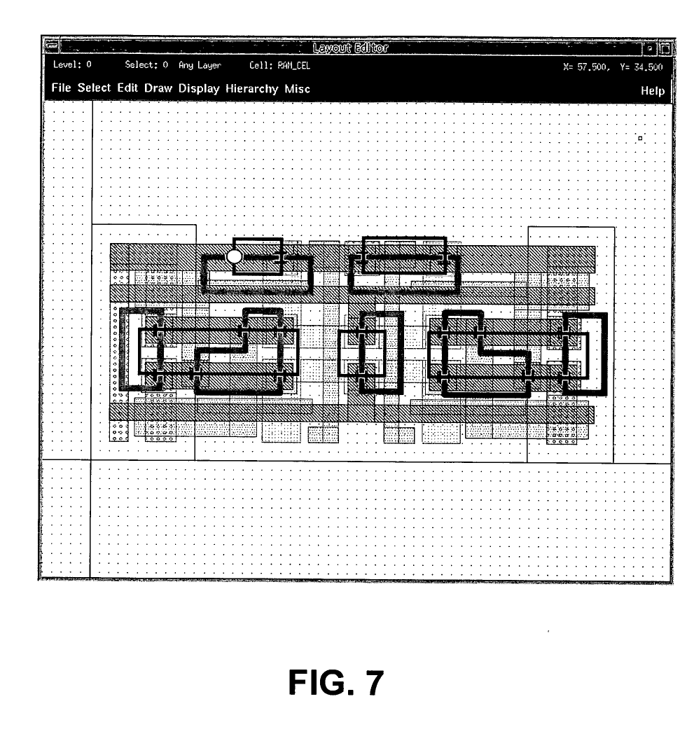

FIG. 7 illustrates an exemplary random access memory (RAM) cell. The RAM cell includes multiple irregularly-spaced contact holes (indicated by dark squares) that may be printed by two sets of polygons (e.g., of two phase shift masks). The first set of polygons (light grey polygons) intersects the desired contact hole locations. The second set of polygons (dark grey polygons) intersects the first set of polygons at the desired contact hole locations. FIG. 7 also illustrates a redundant hole (indicated by the white circle) printed as a design convenience. More details about where and how redundant holes can be printed will be described in Section III below.

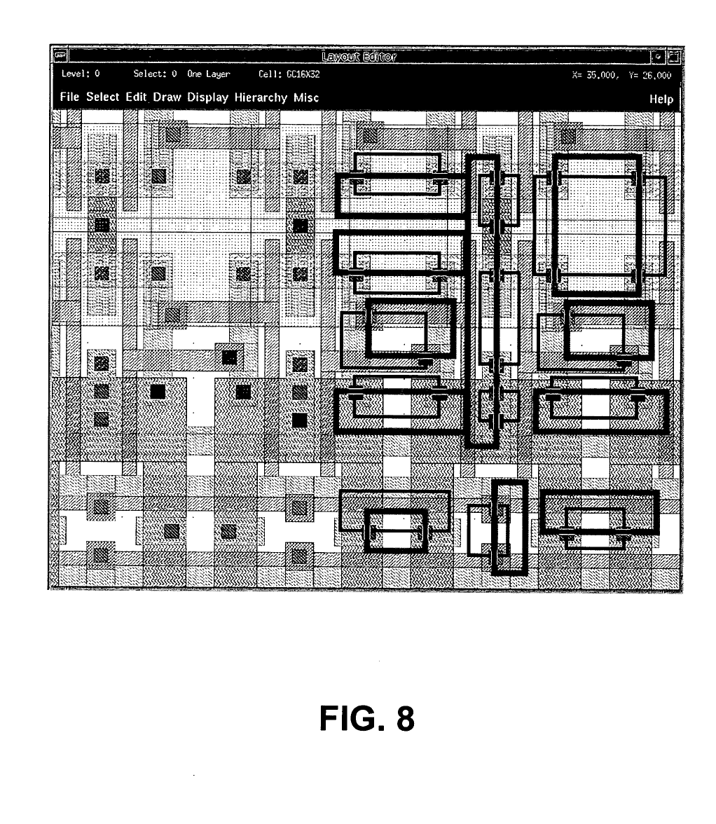

Similar to FIG. 7, FIG. 8 illustrates an exemplary static random access memory (SRAM) cell. The SRAM cell includes multiple irregularly-spaced contact holes (indicated by dark squares) that may be printed by two sets of polygons (e.g., of two phase shift masks). The first set of polygons (light grey polygons) intersects the desired contact hole locations. The second set of polygons (dark grey polygons) intersects the first set of polygons at the desired contact hole locations.

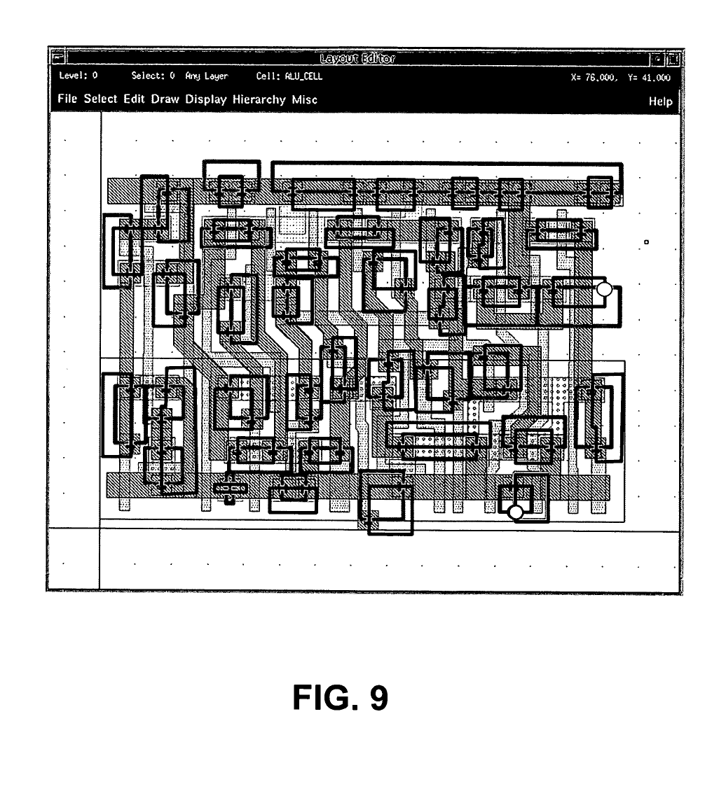

FIG. 9 illustrates an exemplary Arithmetic Logic Unit (ALU) cell. The ALU cell includes multiple irregularly-spaced contact holes (indicated by dark squares) that may be printed by two sets of polygons (e.g., of two phase shift masks). The first set of polygons (light grey polygons) intersects the desired contact hole locations. The second set of polygons (dark grey polygons) intersects the first set of polygons at the desired contact hole locations. Similar to FIG. 7, FIG. 9 illustrates redundant holes printed as a design convenience.

III. Enabling Printing of Redundant or Single Contact Holes

In general, when two polygons intersect, there are typically two locations on each polygon where intersections occur. Consequently, when designing two sets of polygons (e.g., of two phase shift masks), a majority of contact holes will be designed in pairs. While these implementations effectively cover the printing of most desired contact holes, from time to time, a redundant hole or a single contact hole may have to be printed. For example, if the desired contact hole count is odd, a redundant (or dummy) hole may be designed to enable efficient application of the exemplary implementations described herein. A single contact hole may be needed sometimes, for example, in a location that does not have enough space for a redundant hole or if placing a redundant hole is inappropriate according to design rules. In this case, a single contact hole may be printed to complement the various exemplary implementations described herein.

A. Redundant Holes

It is important to design redundant holes at locations that will not interfere with the proper function of the device. For example, a redundant hole should not form unintended contact or connection with any other structure(s) (e.g., metal lines) on the device.

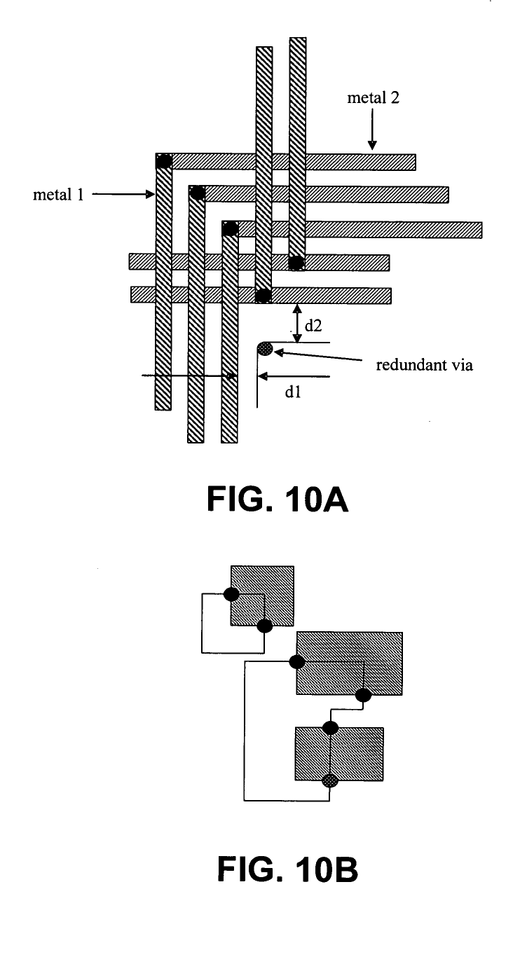

FIG. 10A illustrates an exemplary placement of a redundant hole that does not form unintended contact with the surrounding metal lines. Typically, metal lines are connected by contact holes at their intersections. In FIG. 10A, an odd number of contact holes are designed. In an exemplary implementation, a redundant hole can be placed at an appropriate location (e.g., away from the metal lines) to print an even number of holes. In this exemplary layout, the redundant hole is separated from the metal line array 1 by a distance d1 and separated from the metal line array 2 by a distance d2 to avoid any unintended contact with the metal lines. The values d1 and d2 can be chosen such that under the worst process variations (e.g., misalignment, line width and/or contact hole size variation, etc.) the redundant hole will not connect any unintended metal lines.

FIG. 10B illustrates an exemplary layout of polygons of two phase shift masks that can be used to print the contact holes (including the redundant hole) illustrated in FIG. 10A. In this Figure, polygons of the first mask are represented by clear polygons and polygons of the second mask are represented by filled polygons. Contact holes can be printed at the intersections of the polygons of the two masks.

B. Single Contact Holes

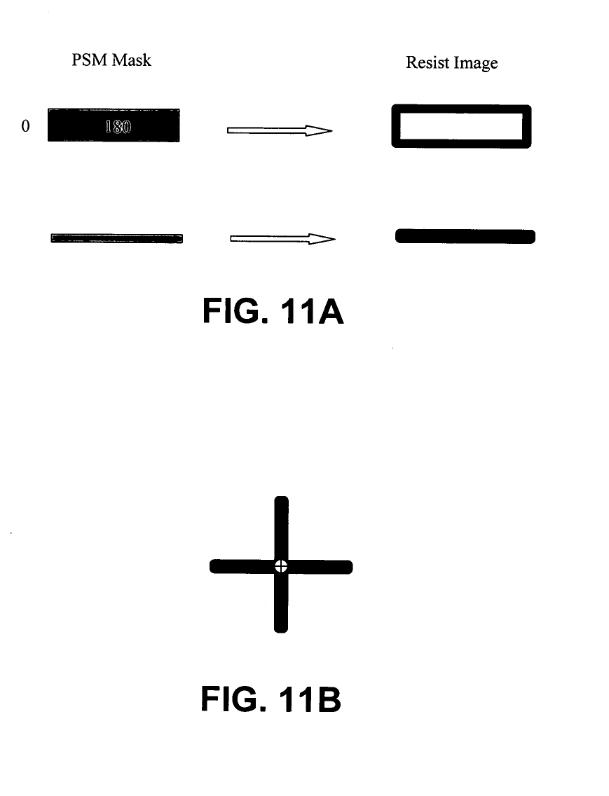

FIG. 11A illustrates an exemplary technique for printing a single contact hole using polygons of phase shift masks.

In the top series of figures, the resist image of a polygon (having a 180° phase shift relative to its surrounding substrate) printed on a wafer is a rectangle having an exposed interior and an unexposed border (indicating by the darkened border). As the polygon becomes smaller, the printed resist image of the polygon will have a smaller exposed interior, which can eventually disappear and result in a single unexposed bar (see bottom figures). If two such small polygons of two masks are aligned orthogonally to each other, the resulting resist image will be a single unexposed dot (which can be developed into a single contact hole). FIG. 11B illustrates the unexposed dot as a white circle at the intersection of two orthogonally oriented bars. In practice, the orthogonal bars will have been exposed (during the second exposure) and will no longer appear in the resist image of FIG. 11B.

The technique described above is merely exemplary. A person skilled in the art will recognize that other techniques known in the art may also be implemented to from single contact holes. For example, certain three-phase phase shift mask technique known in the art may be implemented instead to print single contact holes at certain desired locations to complement the exemplary implementations described herein.

IV. Controlling the Sizes and Shapes of Contact Holes

In general, larger contact holes are more robust than smaller contact holes. Also, square or rectangular contact holes are generally more robust than non-square and non-rectangular (e.g., round, etc.) contact holes of the same design rule. A square or rectangular contact hole typically has up to 36% more contact area than a circular contact hole of the same design rule. Thus, it is desirable to have more control over the sizes and shapes of the contact holes formed on a device.

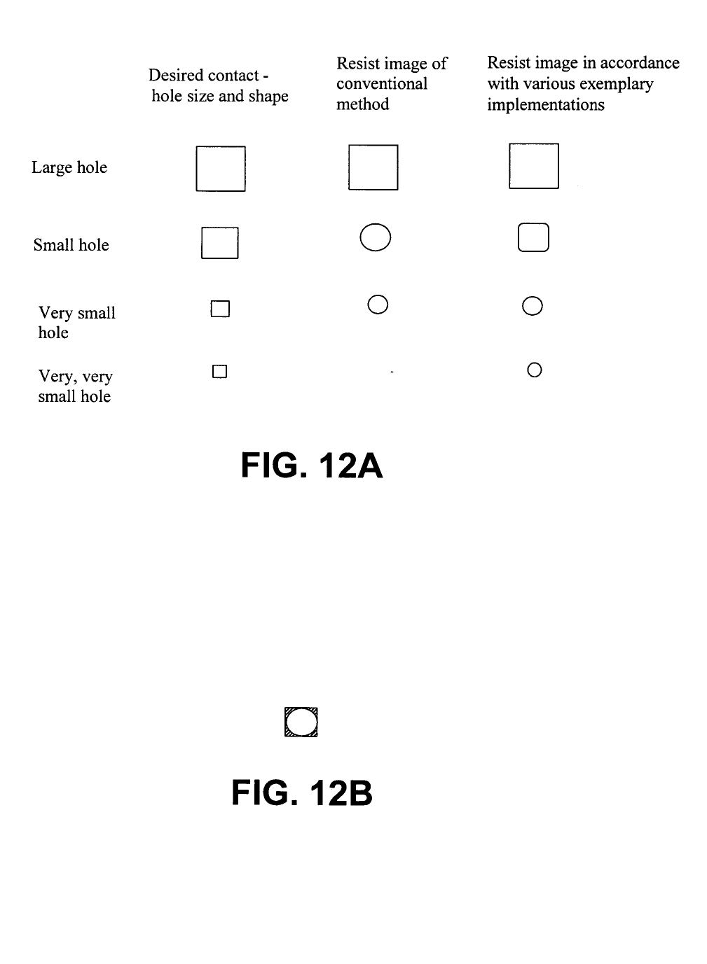

FIG. 12A illustrates exemplary sizes of desired contact holes, the resist images resulting from conventional photolithography to print these contact holes, and the exemplary resist images resulting from the various exemplary implementations described herein to print these contact holes. Due to light diffraction and resist diffusion, as the contact hole size gets smaller, a square hole in a mask may print a circular contact hole. This is illustrated in FIG. 12B. However, application of various exemplary implementations described herein may improve the resolution of the resulting contact holes so that the resist image of smaller contact holes may retain its square or rectangular shape. This Section describes exemplary techniques for controlling the sizes and/or shapes of contact holes to be printed.

A. Add Regulators

In an exemplary implementation, the size and shape of contact holes may be controlled by forming regulators of varying thicknesses around the polygons of each mask.

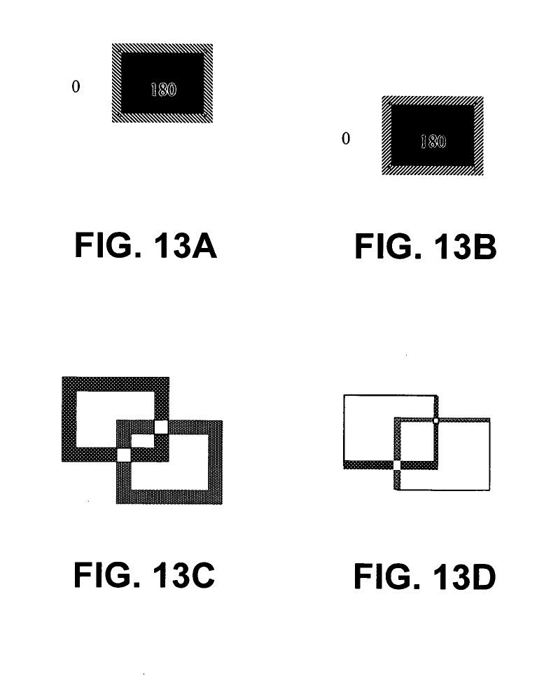

FIGS. 13A-13B illustrate two polygons (e.g., of two phase shift masks), where each polygon has a phase shift of 180° in its interior area relative to its exterior area (e.g., the substrate). Each polygon in FIGS. 13A-13B is bordered by a regulator (the diagonal-line shaded border), such as a chrome regulator. When two phase shift masks each having one of the two polygons are exposed to light successively while intersecting at the locations of the desired contact holes, the printed resist image on the wafer is as shown in FIG. 13C. The two white squares indicate the locations of the desired contact holes. The width and height of these contact holes are substantially defined by the width of the regulators. Thus, by controlling the widths of the regulators bordering polygons, one can control the size and shape of the printed contact holes. FIG. 13D illustrates exemplary contact holes having varying sizes (indicated by the white rectangles) that are printed by polygons having regulators of varying widths. In some implementations, each side of a polygon can have a different width regulator than other sides of the polygon. Techniques for forming regulators are known in the art and need not be described in detail herein.

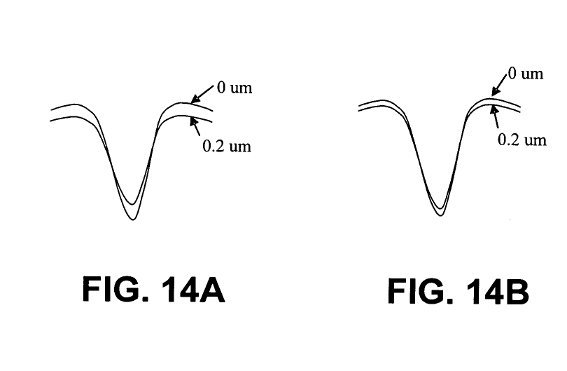

FIG. 14A illustrates an exemplary light intensity distribution of masks having regulators at the focus plane (0 μm) and at a defocus plane (0.2 μm). FIG. 14B illustrates an exemplary light intensity distribution of masks without regulators at the focus plane (0 μm) and at a defocus plane of (0.2 μm). These figures illustrate that masks having regulators tend to retain its image quality at defocus as compared to focus plane better than masks without regulators.

B. Adjust the Angle of Intersection

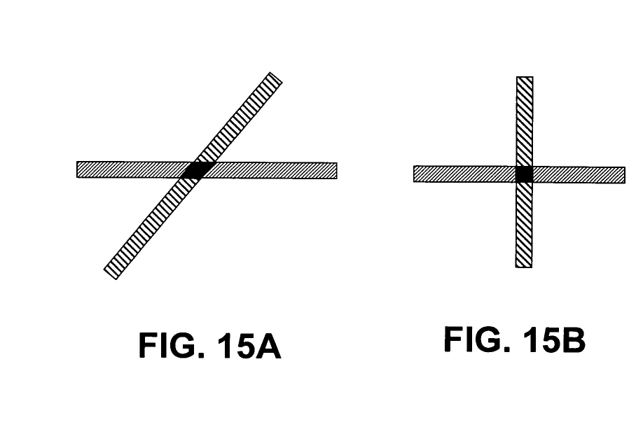

In an exemplary implementation, the regulators of polygons of phase shift masks may be placed at different intersecting angles to control the size and/or shape of the resulting contact holes. FIGS. 15A illustrates two regulators (e.g., of respective polygons) intersecting each other at 45° angle. For ease of explanation, only one side of each intersecting polygon is illustrated. The resulting contact hole is substantially trapezoidal. FIG. 15B illustrates two regulators (of respective polygons) intersecting each other at 90° angle (e.g., orthogonal orientation). The resulting contact hole is substantially square. Thus, control of the intersection angles of polygons (e.g., of different masks) can also provide control over the desired size/shape of the contact holes.

C. Alignment with Metal Lines

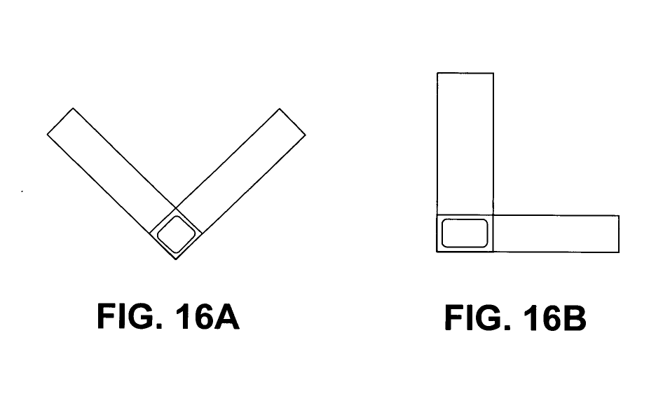

Contact holes are often used to electrically connect multiple metal lines. Thus, alignment and lateral widths of the metal lines to be connected can affect the size and shape of the connecting contact hole. For example, FIG. 16A illustrates a pair of metal lines aligned at 45° angles and being about the same width. In this example, the size of the contact hole being used to connect the metal lines can be maximized by aligning it with the boundaries of the intersecting metal lines. FIG. 16B illustrates another pair of metal lines aligned at 90° angles and one metal line being wider than the other metal line. In this example, the contact hole being used to connect them is substantially rectangular. In an exemplary implementation, for more robust contact holes, the contact holes connecting metal lines are designed: (1) to stay within the boundaries of the metal lines; and (2) to have their edges aligned with the boundaries of the metal lines to maximize the size of the contact holes.

V. Errors and Error Corrections

A. Misalignment Errors

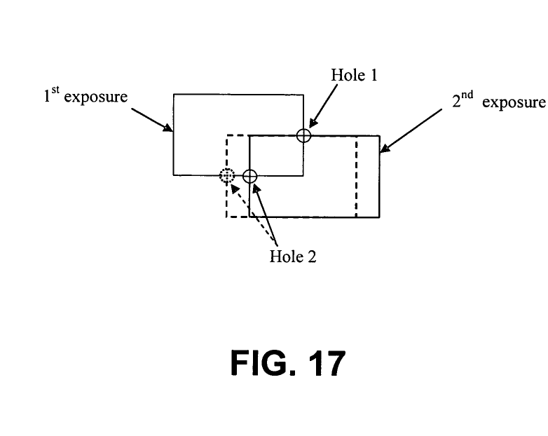

In any photolithography designs, mask misalignment error must be considered. In general, misalignment error increases as more masks are involved in a manufacturing process. However, the exemplary implementations described herein generally incur the same misalignment error(s) as single mask processes. This is illustrated in FIG. 17.

FIG. 17 illustrates two polygons each of a respective one of two phase shift masks. Contact holes 1 and 2 can be printed at the intersections of these polygons after two exposures (each exposure involving one of the two phase shift masks). Hole 1 is not sensitive to a misalignment in the y direction of the first exposure and the x direction of the second exposure. Hole 1 may incur a misalignment error in the x direction if a misalignment occurs in the first exposure but will be unaffected if a misalignment (in the x direction) occurs in the second exposure. Further, hole 1 may incur a misalignment error in the y direction if a misalignment occurs in the second exposure but will be unaffected if a misalignment (in the y direction) occurs in the first exposure. Thus, hole 1 is not subject to cumulative misalignment errors resulting from the two exposures and has the same misalignment tolerance as if it were printed by a single mask process.

Similarly, hole 2 is not sensitive to a misalignment in the x direction of the first exposure and y direction of the second exposure. Hole 2 may incur a misalignment error in the y direction if a misalignment occurs in the first exposure but will be unaffected if a misalignment (in the y direction) occurs in the second exposure. Further, hole 2 may incur a misalignment error in the x direction if a misalignment occurs in the second exposure but will be unaffected if a misalignment (in the x direction) occurs in the first exposure. Thus, hole 2 is not subject to cumulative misalignment errors resulting from the two exposures and has the same misalignment tolerance as if it were printed by a single mask process.

Techniques for correcting and/or compensating for misalignment errors in single exposure processes are well known in the art and need not be described in detail herein.

B. Image Shift Due to Asymmetry

Due to geometrical asymmetry between interior and exterior regions of polygons, the resist image of lines printed at the borders of the polygons may shift in different directions (e.g., toward the inside or outside of the polygons).

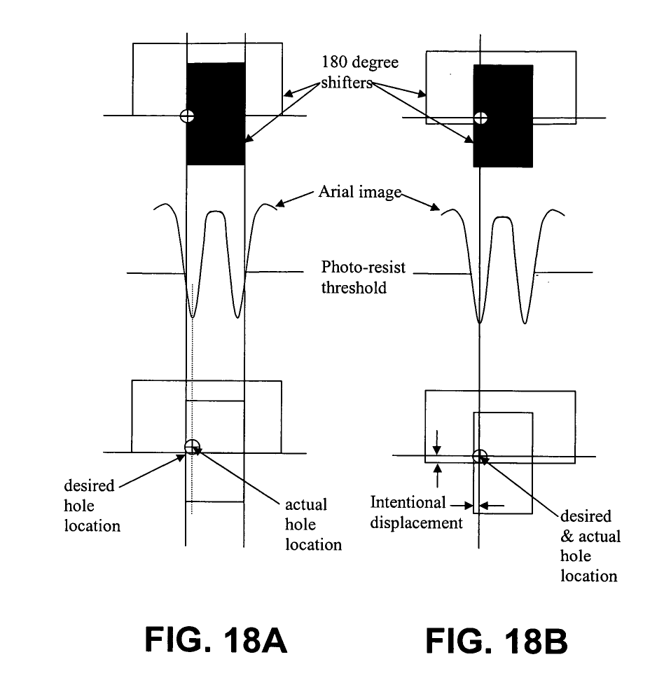

For example, the top figure in FIG. 18A illustrates an exemplary alignment of two polygons (i.e., clear & filled polygons) intersecting each other to print contact holes. For ease of explanation, the second contact hole printed at the other intersection of the two polygons is not drawn. The bottom figure of FIG. 18A illustrates the resist image of the printed contact hole location which is slightly shifted in the +y direction and in the +x direction (when using the xy coordinates as reference coordinates) than the desired contact hole location.

Given the intensity of light used in a photolithography exposure, a person skilled in the art can calculate the amount and direction of the slight shift in the resist image. Thus, in an exemplary implementation, one or more polygons may be intentionally shifted in the opposite direction by a pre-calculated amount. The top figure in FIG. 18B illustrates a slight shift in the −y direction for the clear polygon and a slight shift in the −x direction for the filled polygon. The resulting contact hole then may be printed at substantially the desired location as shown in the bottom figure of FIG. 18B.

Of course, the example provided above is merely exemplary. Depending on the specific design of the polygons and a given exposure environment, the printed resist images of one or more polygons may be shifted in one or more other directions (e.g., in opposite directions of the example provided above).

VI. Other Phase Shift Masks

The various implementations described above generally involve two-phase phase shift masks. However, a person skilled in the art will recognize that masks having more than two phases may also be used in accordance with embodiments described herein. For example, three-phase or four-phase phase shift masks may be implemented.

A. Three-Phase Phase Shift Masks

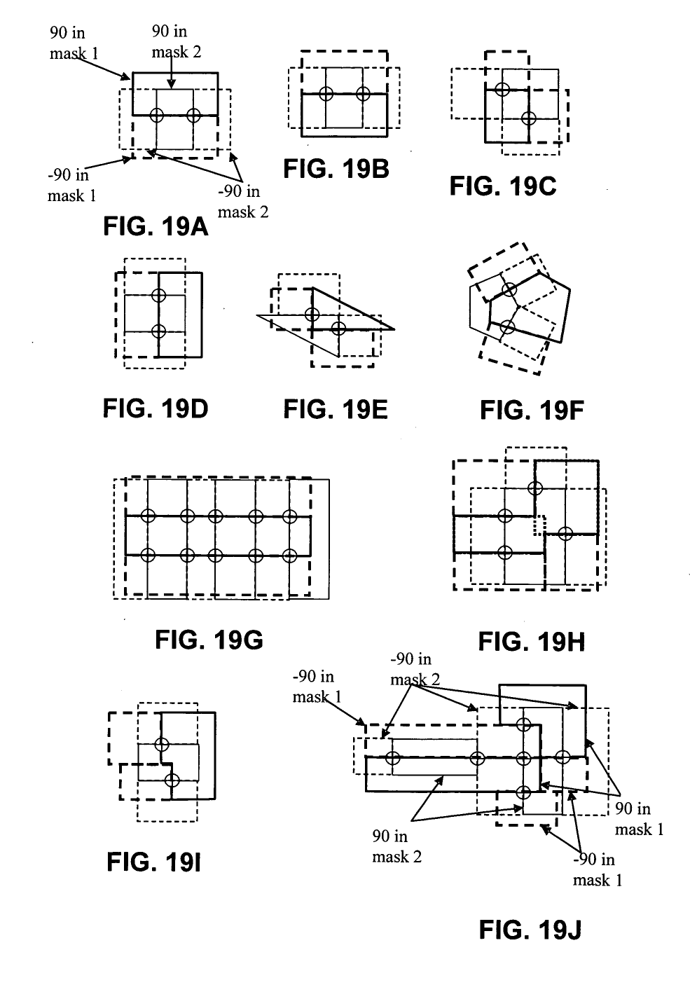

FIGS. 19A-19J illustrate exemplary implementations of three-phase phase shift masks to print irregularly-spaced contact holes. Previously in two-phase phase shift masks, the interior region of each polygon has a 180° phase shift relative to the exterior region. In an exemplary implementation, two three-phase phase shift masks may be designed based on the two sets of polygons of two two-phase phase shift masks, respectively, by applying the following transformation steps: (1) for each polygon of a first or second set of polygons, duplicate the polygon along the edges (or border) where the polygon intersects desired contact holes, the duplicated polygon(s) of each polygon should generally have the same shape as its corresponding original polygon; and (2) assign the original polygons a 90° phase shift and assign the duplicated polygons a −90° phase shift. In some cases an original polygon may have more than one duplicated polygons. For example, in FIG. 19A, the solid lines indicate the original polygons, where the thick solid line indicates a polygon of mask 1 and thin solid line indicates a polygon of mask 2. In this example, the polygon of mask 1 has two duplicated polygons, which are indicated by thin dashed lines, because two edges of the original polygon of mask 1 intersect desired contact holes. The polygon of mask 2 has one duplicated polygon, which is indicated by a thick dashed line, because just one edge of the original polygon of mask 2 intersects the desired contact holes. For ease of explanation only, these edges separating the original polygons from the duplicated polygons of three-phase phase shift masks will be referred to as the “180° phase shift edges.” In general, the background of three-phase phase shift masks has a 0° phase shift. Other exemplary polygon alignments are shown in FIGS. 19B-19J.

When the two three-phase phase shift masks are successively exposed, contact holes are printed at the intersections of the 180° phase shift edges of polygons of the first mask and the 180° phase shift edges of polygons of the second mask.

In another exemplary implementation, the three-phase phase shift masks may be designed directly (without first determining the polygons for the two-phase phase shift masks) by determining a first set of polygons each intersecting desired irregularly-spaced contact holes at their 180° phase shift edges and determining a second set of polygons each intersecting the first set of polygons at the locations of the desired irregularly-spaced contact holes.

The exemplary implementation described above is merely illustrative. A person skilled in the art will recognize that other techniques for implementing three-phase phase shift masks can also be implemented in accordance with design choice and/or requirements.

B. Four-Phase Phase Shift Masks (Vortex Masks)

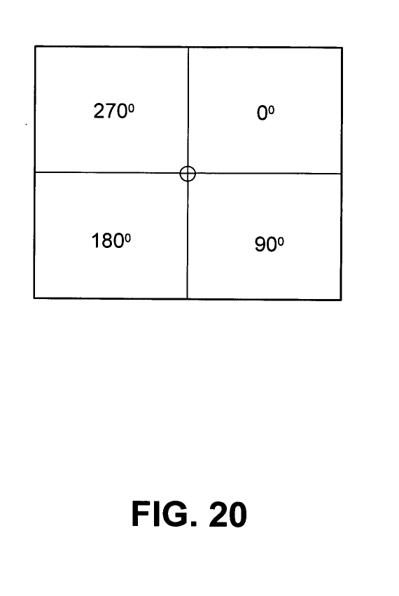

FIG. 20 illustrates an exemplary four-phase phase shift mask having four phases on the mask. A four-phase phase shift mask may also be referred to as a vortex mask. In FIG. 20, four polygons are formed on the mask. The interior region of each polygon has a different phase shift relative to the other polygons: 0°, 90°, 180°, 270°. In this implementation, a single contact hole (indicated by a circle) can be printed at the center of the four phase shift polygons during a single exposure process. During an exposure, light in the 0° and 180° phase shift areas destructively interferes with each other at the center. Likewise, light in the 90° and 270° phase shift areas destructively interferes with each other. As a result, an unexposed dot at the center of the polygons will be printed in the resist image after the exposure. The unexposed dot can subsequently be developed into a contact hole.

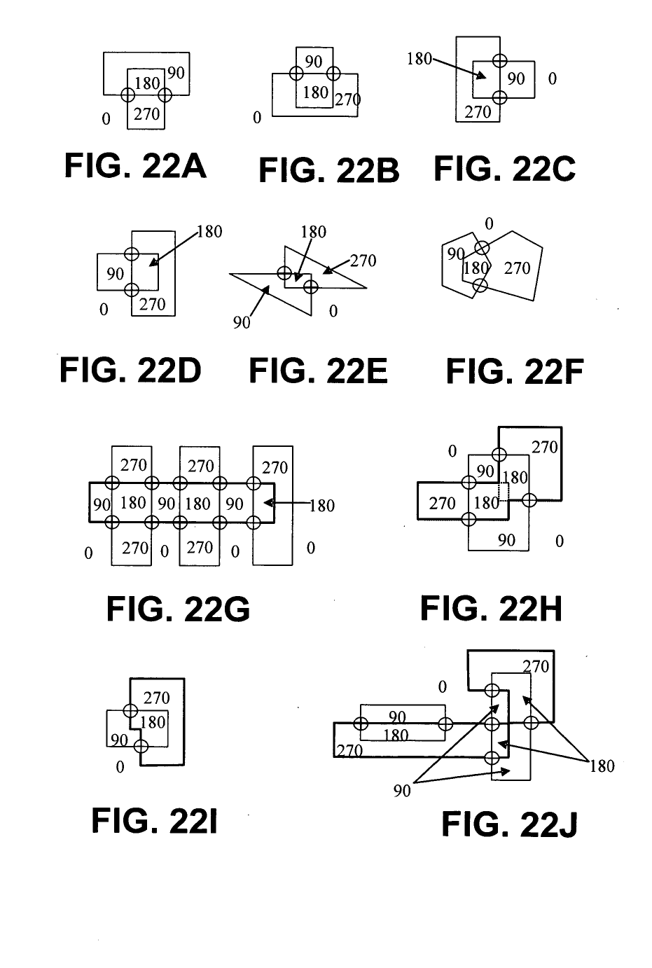

In another exemplary embodiment, the substrate of the mask may have one phase shift value (0°) and three polygons having three other different phase shift areas can be used to form a four-phase phase shift mask. This mask may be used to print even-numbers of irregularly-spaced contact holes. In an exemplary implementation, a four-phase phase shift mask may be formed using the two-phase phase shift masks described in exemplary implementations herein (e.g., see FIG. 22). Assume the interior regions of all polygons on a first (two-phase phase shift) mask is π₁ and all interior regions of all polygons on a second (two-phase phase shift) mask π₂, then a four-phase phase shift mask can be formed by applying the following transformation:
π₁ AND π₂=180° phase shift region
π₁ SUBTRACT π₂=90° phase shift region
π₂ SUBTRACT π₁=270° phase shift region
background−(π₁ OR π₂)=0° phase shift region (e.g., the rest of the substrate of the mask)

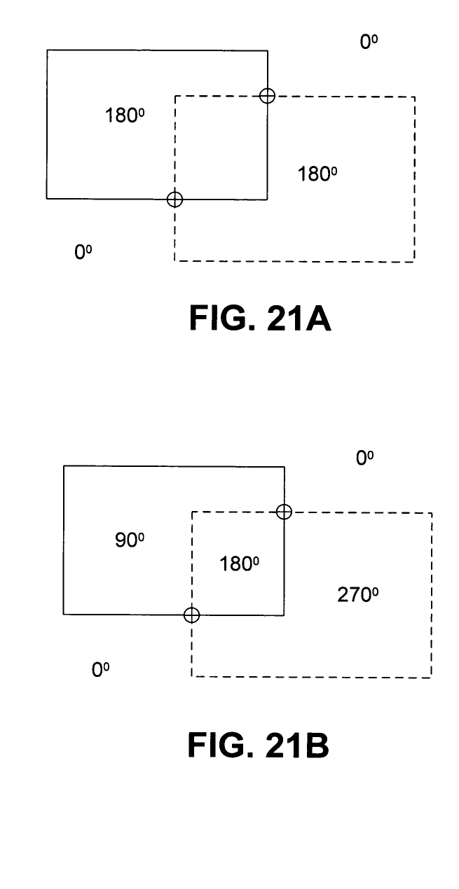

FIGS. 21A & 21B illustrate how to form an exemplary four-phase phase shift mask by applying the above transformation to two polygons of two two-phase phase shift masks. FIG. 21A illustrates an exemplary alignment of two two-phase phase shift masks each having a single polygon. The first polygon of the first mask is indicated by solid lines and the second polygon of the second mask is indicated by dashed lines. As described in other Sections of this application, two contact holes may be printed at the intersections of these two polygons so long as the relative phase shift between the interior regions and the exterior regions of the polygons is sufficient to effect destructive light interference (e.g., 180° relative phase shift difference).

FIG. 21B illustrates a four-phase phase shift mask that can be formed by applying the transformation above to the polygons of the first and second masks. The four-phase mask includes three polygons each having a different phase shift relative to the other polygons in its interior region (i.e., 90°, 180°, 270°) and the substrate provides the fourth phase (i.e., 0°). A single four-phase phase shift mask may replace the two two-phase shift masks to print irregularly-spaced contact holes on a wafer in a single exposure step.

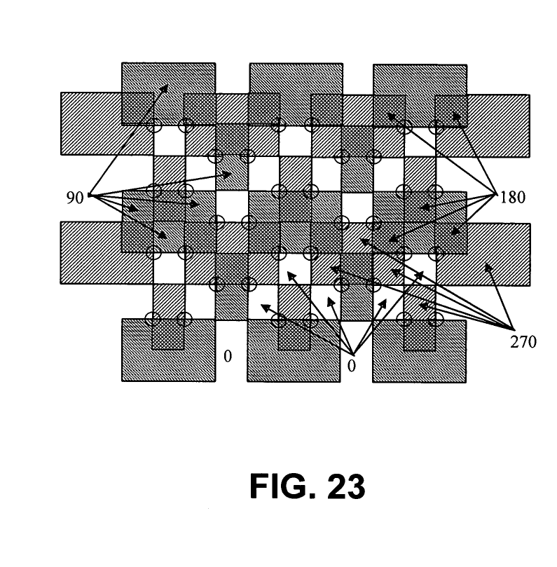

FIG. 22A-22J illustrate exemplary alignment of polygons of a four-phase phase shift mask (vortex mask). FIG. 23 illustrates an exemplary polygon layout of a four-phase phase shift mask for printing contact holes of a SRAM device.

The exemplary implementation described above is merely illustrative. A person skilled in the art will recognize that other techniques for forming and/or using four-phase phase shift masks can also be implemented in accordance with design choice and/or requirements. For example, a four-phase phase shift mask may be formed by first determining two sets of polygons in accordance with implementations described herein without explicitly assigning the polygons to two two-phase phase shift masks, then applying the above transformation to form the four-phase phase shift mask. Further, one may also design a four-phase phase shift mask by determining a first set of polygons each having a 90° phase shift in its interior region and a second set of polygons each having a 270° phase shift in its interior region, then determine the 180° and 0° regions by derivation. For example, typically, the 180° polygons on a vortex mask are surrounded by one or more 90° phase shift polygons and one or more 270° phase shift polygons. Therefore, one can derive the locations of the 180° phase shift polygons when one has knowledge of the locations of the 90° and 270° phase shift polygons. Also, the substrate outside of all polygons on the mask generally has 0° phase shift. Therefore, one can easily derive the phase shift of the remaining areas outside of the 90° and 270° phase shift polygons (i.e., 0° phase shift).

The transformation described above is merely exemplary. A person skilled in the art will recognize that other transformations may also be applied to transform one or more multi-phase phase shift masks to another one or more multi-phase phase shift masks. For example, a set of two-phase phase shift masks can be obtained from a four-phase phase shift mask by reversing the transformation described above.

VII. An Exemplary Process for Designing Phase Shift Masks

In general, when designing phase shift masks in accordance with exemplary implementations described herein, the masks should print contact holes where desired and not where undesired.

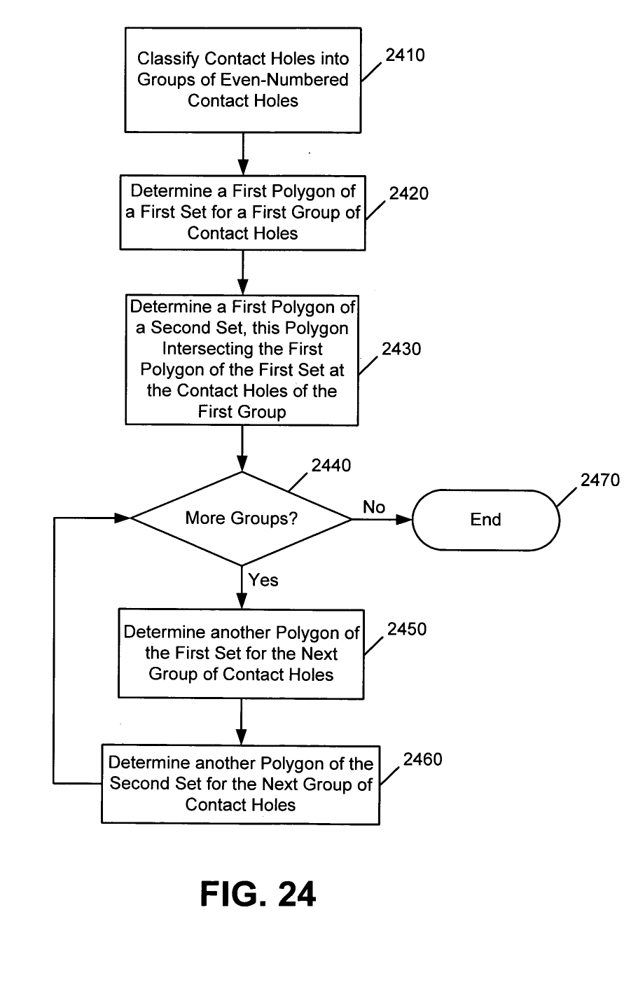

FIG. 24 illustrates an exemplary process for designing phase shift masks in accordance with the exemplary implementations described herein.

At step 2410, desired contact holes are classified into even-numbered groups. For example, each group may include two contact holes. Redundant (or dummy) holes may be added into any group whenever necessary in accordance with design rules. For any desired contact hole that cannot be paired with other contact holes into an even-number group and if a redundant hole cannot be added nearby, a single contact hole may be designed and implemented in accordance with exemplary implementations described above in Section III and/or other techniques known in the art.

At step 2420, determine a first polygon of a first set of polygons for a first group of contact holes. The first polygon should intersect all the contact holes within the first group. The size and shape of each polygon may be determined based on available space and locations of nearby groups.

At step 2430, determine a first polygon of a second set of polygons for the first group of contact holes. The first polygon of the second set should intersect the first polygon of the first set at only the locations of the desired contact holes of the first group.

At step 2440, whether another group exists is determined.

If not, the process ends at step 2470.

If another group exists, at step 2450, a second polygon of the first set for the next group of contact holes is determined. This polygon should intersect all the contact holes within the next group.

At step 2460, a second polygon of the second set for the next group of contact hole is determined. This polygon should intersect the second polygon of the first set determined at step 2450 at only the locations of the desired contact holes of the next group. Steps 2450 and 2460 are repeated for the next group until all groups have been processed and the process ends at step 2470.

In an exemplary implementation, for ease of design, polygons of a first set may be distinguished by a different color than polygons of a second set. In general, polygons that overlap or contact each other (other than at the locations of the desired contact holes) must be of the same set (or color). For improved efficiency, overlapping polygons of the same set (or color) can be merged into one polygon. In addition, for improved robustness, polygons that are close to each other should also be of the same set (or color).

The two sets of polygons formed by the process described above then can be implemented to form one or more two-phase, three-phase, or four-phase (or other multi-phase) phase shift masks. For example, the first set of polygons may be assigned to a first mask and the second set of polygons may be assigned to a second mask to form two two-phase phase shift masks or two three-phase phase shift masks which can be used to print irregularly-spaced contact holes as described herein. Alternatively, a four-phase phase shift mask can be formed by applying the transformation set forth in Section VI.B. above to the two sets of polygons. The single four-phase phase shift mask can be used to print irregularly-spaced contact holes.

The various exemplary implementations described herein are merely illustrative. One skilled in the art will recognize that other design techniques may be used to print irregularly-spaced contact holes with one or more phase shift masks. Further, one skilled in the art will recognize that the described implementations are not precluded from being used to print regularly-spaced contact holes exclusively, or in combination with printing irregularly-spaced contact holes.

VIII. Resolving Phase Conflict

From time to time, a phase conflict may occur when two polygons of different sets overlap or contact each other at unintended locations. For ease of explanation, polygons causing a phase conflict will be referred to as offending polygons. When phase conflict occurs, one or more of the following techniques may be used to resolve the issue.

A. Reassign One or More Offending Polygons to a Different Set

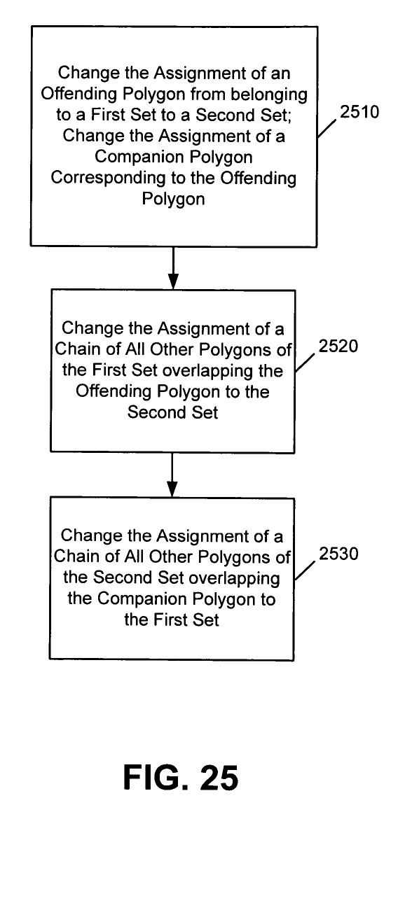

FIG. 25 illustrates an exemplary process for resolving a phase conflict.

At step 2510, change the assignment of an offending polygon from belonging to a first set to a second set. For ease of explanation, we will refer to polygons of a first set as being red and polygons of a second set as being blue. If red and blue polygons overlap (or intersect) each other at unintended locations, a phase conflict occurs. Thus, in this implementation, an offending red polygon is changed to be a blue polygon (“first new blue polygon”).

Typically, each polygon on a first set intersects a corresponding polygon of a second set to enable printing of at least two contact holes. Thus, the offending red polygon in this example also legitimately intersects another blue polygon (i.e., a companion polygon of the second set of polygons). Therefore, when the offending red polygon is changed to be the first new blue polygon, one will have to change the color of the companion polygon to red (“companion new red polygon”). In other words, the companion polygon of the second set (intersecting the offending polygon of the first set) is reassigned to be of the first set.

At step 2520, change the assignment of a chain of all other polygons that are overlapping or touching the offending polygon of step 2510 to belong to the second set. For example, if a second red polygon overlaps the first new blue polygon, that second red polygon should be changed to a second new blue polygon. If a third red polygon overlaps either the first new blue polygon or the second new blue polygon, then the third red polygon should be changed to a third new blue polygon and so forth until all polygons of different colors overlapping each other at unintended locations (i.e., not the locations of the desired contact holes) have been changed to have the same color.

At step 2530, change the assignment of a chain of all other polygons that are overlapping or touching the companion polygon of step 2510 to belong to the first set. For example, if a second blue polygon overlaps the companion new red polygon, that second blue polygon should be changed to a second new red polygon. If a third blue polygon overlaps either the companion new red polygon or the second new red polygon, then the third blue polygon should be changed to a third new red polygon and so forth until all polygons of different colors overlapping each other at unintended locations (i.e., not the locations of the desired contact holes) have been changed to have the same color.

B. Adjust the Shapes of the Polygons

Another technique to resolve phase conflict is to change the shapes of one or more offending (or nearby) polygons. For example, smaller polygons may be used to replace one or both offending polygons overlapping at unintended locations.

C. Re-Classify (or Regroup) Contact Holes

Another technique to resolve phase conflict is to re-classify or regroup contact holes to be printed by the offending polygons. For example, contact holes of one group may be assigned to another group to enable, for example, a redesign of the size/shape of the offending polygons.

D. Add Redundant Contact Holes

Another technique to resolve phase conflict is to add one or more redundant (or dummy) holes to enable redesign or removal of one or more offending polygons.

E. Print Single Contact Holes

Another technique to resolve phase conflict is to print one or more single contact holes to eliminate the need of one or more offending polygons.

IX. An Exemplary Operating Environment

The embodiments described herein may be implemented in an operating environment comprising software installed on a computer, in hardware, or in a combination of software and hardware.

The software and/or hardware would typically include some type of computer-readable media which can store data and logic instructions that are accessible by the computer or the processing logic within the hardware. Such media might include, without limitation, hard disks, floppy disks, flash memory cards, digital video disks, random access memories (RAMs), read only memories (ROMs), and the like.

X. Conclusion

The foregoing examples illustrate certain exemplary embodiments from which other embodiments, variations, and modifications will be apparent to those skilled in the art. The inventions should therefore not be limited to the particular embodiments discussed above, but rather are defined by the claims. Furthermore, some of the claims may include alphanumeric identifiers to distinguish the elements thereof. Such identifiers are merely provided for convenience in reading, and should not necessarily be construed as requiring or implying a particular order of steps, or a particular sequential relationship among the claim elements.

1. A method for printing irregularly-spaced contact holes of a semiconductor device, comprising:
printing a semiconductor wafer using at least one multi-phase phase shift mask, said mask:
having a plurality of polygons as phase shifters on a substrate;
at least one of said polygons being irregularly-spaced with respect to another of said polygons; and
one or more of said polygons providing sufficient phase shift relative to an exterior region of said polygons to effect destructive light interference for printing irregularly-spaced contact holes on one or more phase shift edges.

2. The method of claim 1, wherein said printing includes using two two-phase phase shift masks each having a respective plurality of polygons to print irregularly-spaced contact holes.

3. The method of claim 2, wherein polygons of one of said two masks intersect polygons of another of said two masks at the locations of said irregularly-spaced contact holes.

4. The method of claim 1, wherein said printing includes using two three-phase phase shift masks each having a respective plurality of polygons to print irregularly-spaced contact holes.

5. The method of claim 4, wherein polygons of one of said two masks intersect polygons of another of said two masks at the locations of said irregularly-spaced contact holes.

6. The method of claim 4, wherein the phase shift edges of one or more polygons of one of said two masks intersect the phase shift edges of one or more polygons of another of said two masks.

7. The method of claim 1, wherein said printing includes using a single four-phase phase shift mask having said plurality of polygons to print irregularly-spaced contact holes.

8. The method of claim 1, wherein said sufficient phase shift is a 180° relative phase shift.

9. The method of claim 1, further comprising:
printing at least one redundant hole at a location that does not interfere with the proper function of said device.

10. The method of claim 1, further comprising:
printing at least one redundant hole at a location that does not cause an unintended connection.

11. The method of claim 1, further comprising:
printing a single contact hole by using a polygon of a first plurality of polygons and a polygon of a second plurality of polygons, wherein said polygons intersect each other at substantially a single location of said single contact hole.

12. The method of claim 1, wherein at least one of said polygons includes a rectangle.

13. The method of claim 1, wherein at least one of polygons includes a smooth curve.

14. The method of claim 1, wherein at least one of said polygons includes a triangle.

15. A method for printing irregularly-spaced contact holes of a semiconductor device, comprising:
printing a semiconductor wafer using at least one multi-phase phase shift mask, said mask:
having a plurality of polygons as phase shifters on a substrate;
at least one of said polygons being irregularly-spaced with respect to another of said polygons; and
one or more of said polygons providing sufficient phase shift relative to an exterior region of said polygons to effect destructive light interference for printing irregularly-spaced contact holes, including at least one redundant hole, on one or more phase shift edges.

16. A method for forming one or more phase shift masks for printing irregularly-spaced contact holes on a semiconductor wafer, comprising:
classifying contact holes into groups, each group comprising at least two contact holes;
determining a first set of polygons:
each of said first set of polygons intersecting all contact holes of one of said groups; and
at least one polygon of said first set being irregularly-spaced with respect to one or more other polygons of said first set;
determining a second set of polygons:
each of said second set of polygons intersecting at least one polygon of said first set at the locations of the contact holes intersected by said at least one polygon of said first set;
forming a phase shift in an interior region of each polygon relative to an exterior region such that said interior region provides sufficient phase shift relative to an exterior region of said polygon to effect destructive light interference during a light exposure for printing irregularly-spaced contact holes along one or more phase shift edges; and
forming one or more phase shift masks based on said first and second sets of polygons.

17. The method of 16, wherein said forming one or more phase shift masks includes forming a first two-phase phase shift mask using said first set of polygons and forming a second two-phase phase shift mask using said second set of polygons.

18. The method of 16, wherein said forming one or more phase shift masks includes forming a first three-phase phase shift mask based on first set of polygons and forming a second three-phase phase shift mask based on second set of polygons.

19. The method of 16, wherein said forming one or more phase shift masks includes forming a four-phase phase shift mask based on said first set of polygons and said second set of polygons.

20. The method of claim 16, wherein said sufficient phase shift is a 180° relative phase shift.

21. The method of claim 16, wherein said classifying includes:
adding one or more redundant holes to one or more groups.

22. The method of claim 16, further comprising:
resolving a phase conflict among one or more polygons of said first and second sets of polygons.

23. The method of claim 22, wherein said resolving includes:
changing an assignment of an offending polygon causing said phase conflict from being of said first set to being of said second set; and changing an assignment of a companion polygon of said second set intersecting said offending polygon from being of said second set to being of said first set.

24. The method of claim 23, further comprising:
changing an assignment of another polygon of one of said first and second sets overlapping one of said offending and companion polygons from being of one set to being of another set.

25. The method of claim 22, wherein said resolving includes:
changing the shape of one or more offending polygons causing said phase conflict.

26. The method of claim 22, wherein said resolving includes:
printing a redundant hole to enable a redesign of one or more offending polygons causing said phase conflict.

27. The method of claim 22, wherein said resolving includes:
printing a single contact hole to enable a removal of one or more offending polygons causing said phase conflict.

28. The method of claim 16, wherein at least one polygon of said first and second sets includes a regulator.

29. The method of claim 28, wherein said regulator includes chrome.

30. The method of claim 16, wherein at least one polygon of said first set intersects at least one polygon of said second orthogonally.

31. The method of claim 16, wherein at least one of said irregularly-spaced contact holes is being used to connect metal lines and said contact hole is designed to align with at least one boundary of said metal lines.

32. The method of claim 16, wherein one or more polygons of said first and second set are shifted in an opposite direction of a pre-calculated image shift error.

33. A computer-implemented application for forming phase shift masks capable of printing irregularly-spaced contact holes of a semiconductor device, comprising:
computer-implemented logic instructions that, when executed on a processor,
classify contact holes into groups, each group comprising at least two contact holes;
determine a first set of polygons:
each of said first set of polygons intersecting all contact holes of one of said groups; and
at least one polygon of said first set being irregularly-spaced with respect to one or more other polygons of said first set;
determine a second set of polygons:
each of said second set of polygons intersecting at least one polygon of said first set at the locations of the contact holes being intersected by said at least one polygon of said first set;
form a phase shifter in an interior region of each polygon such that said interior region provides sufficient phase shift relative to an exterior region of said polygon to effect destructive light interference during a light exposure for printing irregularly-spaced contact holes on one or more phase shift edges; and
form one or more phase shift masks based on said first and second sets of polygons.

34. The computer-implemented application of 33, wherein said logic instructions to form one or more phase shift masks include logic instructions that, when executed, form a first two-phase phase shift mask using said first set of polygons and form a second two-phase phase shift mask using said second set of polygons.

35. The computer-implemented application of 33, wherein said logic instructions to form one or more phase shift masks include logic instructions that, when executed, form a first three-phase phase shift mask based on said first set of polygons and form a second three-phase phase shift mask based on said second set of polygons.

36. The computer-implemented application of 33, wherein said logic instructions to form one or more phase shift masks include logic instructions that, when executed, form a four-phase phase shift mask based on said first set of polygons and said second set of polygons.

37. The computer-implemented application of claim 33, wherein said sufficient phase shift is a 180° relative phase shift.

38. The computer-implemented application of claim 33, further comprising logic instructions that, when executed:
resolve a phase conflict among one or more polygons of said first and second sets of polygons.

39. The computer-implemented application of claim 33, wherein said logic instructions to classify include logic instructions that, when executed:
add one or more redundant holes to one or more groups.

40. A semiconductor device having contact holes being printed by a process comprising:
printing a semiconductor wafer using at least one multi-phase phase shift mask, said mask:
having a plurality of polygons as phase shifters on a substrate;
at least one of said polygons being irregularly-spaced with respect to another of said polygons; and
one or more of said polygons providing sufficient phase shift relative to an exterior region of said polygons to effect destructive light interference for printing irregularly-spaced contact holes along one or more phase shift edges.

41. The device of claim 40, wherein said printing includes using two two-phase phase shift masks each having a respective plurality of polygons to print irregularly-spaced contact holes.

42. The device of claim 40, wherein said printing includes using two three-phase phase shift masks each having a respective plurality of polygons to print irregularly-spaced contact holes.

43. The device of claim 40, wherein said printing includes using a single four-phase phase shift mask having said plurality of polygons to print irregularly-spaced contact holes.

44. A method for forming at least one phase shift mask for printing irregularly-spaced contact holes on a semiconductor wafer, comprising:
classifying contact holes into groups, each group comprising at least two contact holes;
determining a first set of polygons having a first relative phase shift value:
each of said first set of polygons partially overlapping contact holes of one of said groups;
determining a second set of polygons having a second relative phase shift value:
each of said second set of polygons:
contacting at least one corresponding polygon of said first set adjacent to the locations of the contact holes overlapped by said at least one corresponding polygon of said first set; and
partially overlapping said contact holes being partially overlapped by said at least one corresponding polygon of said first set;
determining a third set of polygons having a third relative phase shift value, said third set of polygons being substantially surrounded by said first and second sets of polygons; and
forming at least one phase shift mask based on said first, second, and third sets of polygons.

45. The method of claim 44, wherein each polygon of said third set partially overlapping contact holes being partially overlapped by a corresponding polygon of said first set and a corresponding polygon of said second set that substantially surround said polygon of said third set.

46. The method of claim 44, wherein said first and second relative phase shifts are 90 degree and 270 degree phase shifts, respectively.

47. The method of claim 44, wherein said third relative phase shift is 180 degree phase shift.

48. The method of claim 44, wherein an exterior region outside of said first, second, and third sets of polygons has a fourth relative phase shift.

49. The method of claim 48, wherein said fourth relative phase shift is 0 degree phase shift.

50. The method of claim 44, wherein at least one polygon of said first set being irregularly-spaced with respect to one or more other polygons of said first set.

51. A computer-implemented application for forming phase shift masks capable of printing irregularly-spaced contact holes of a semiconductor device, comprising:
computer-implemented logic instructions that, when executed on a processor,
classify contact holes into groups, each group comprising at least two contact holes;
determine a first set of polygons having a first relative phase shift value:
each of said first set of polygons partially overlapping contact holes of one of said groups;
determine a second set of polygons having a second relative phase shift value:
each of said second set of polygons:
contacting at least one corresponding polygon of said first set adjacent to the locations of the contact holes overlapped by said at least one corresponding polygon of said first set; and
partially overlapping said contact holes being partially overlapped by said at least one corresponding polygon of said first set;
determine a third set of polygons having a third relative phase shift value, said third set of polygons being substantially surrounded by said first and second sets of polygons; and
form at least one phase shift mask based on said first, second, and third sets of polygons.

52. A phase-shift mask formed by a process comprising the steps of:
classifying contact holes into groups, each group comprising at least two contact holes;
determining a first set of polygons having a first relative phase shift value:
each of said first set of polygons partially overlapping contact holes of one of said groups;
determining a second set of polygons having a second relative phase shift value:
each of said second set of polygons:
contacting at least one corresponding polygon of said first set adjacent to the locations of the contact holes overlapped by said at least one corresponding polygon of said first set; and
partially overlapping said contact holes being partially overlapped by said at least one corresponding polygon of said first set;
determining a third set of polygons having a third relative phase shift value, said third set of polygons being substantially surrounded by said first and second sets of polygons; and
forming at least one phase shift mask based on said first, second, and third sets of polygons.
